(19) United States
(12) Patent Application Publication
(10) Pub. No.: US 2019/0098799 A1
(43) Pub. Date: Mar. 28, 2019

(54) THERMAL ENCLOSURE

(71) Applicant: Dura Operating, LLC, Auburn Hills, MI (US)

(72) Inventor: Brandon Keith Richards, Detroit, MI (US)

(21) Appl. No.: 15/715,525

(22) Filed: Sep. 26, 2017

(51) Int. Cl. H05K 7/20; B60R 16/023; F25B 21/02; H05K 9/00

(52) U.S. Cl. CPC H05K 7/20863; B60R 16/0239; F25B 21/02; H05K 7/20872; H05K 9/0015; B60Y 2306/05; H05K 5/03; H05K 7/20145; H05K 7/20172; H05K 7/20209; H05K 7/20254; H05K 7/20272; H05K 7/20281; B60Y 2410/10

(57) ABSTRACT

An enclosure for convection cooling an electronic module in a motor vehicle includes a cold plate for mounting the electronic module thereon. A cover is attached to the bottom plate, and the cover and the bottom plate define a cavity. A plurality of inlets are formed in the cover in fluid communication with the cavity. A plurality of outlets are formed in the cover in fluid communication with the cavity, the outlets spaced apart from and opposite the inlets. An inlet manifold is disposed in fluid communication with the plurality of inlets, and a plurality of fans is disposed in fluid communication with the cavity, each of the plurality of fans having an inlet side in fluid communication with an outlet side.

### FIELD

The present disclosure relates generally to high power electronics in motor vehicles, and more specifically to thermally controlled enclosure for cooling high power electronics in motor vehicles.

### BACKGROUND

The statements in this section merely provide background information related to the present disclosure and may or may not constitute prior art.

Vehicle systems have become increasingly complex with as the quantity and variety of systems operated or controlled electronically has grown. To manage a wide variety of parameters associated with engine, steering, braking, suspension, navigation, advanced driver assistance systems (ADAS), and so forth, increasingly powerful computer processors are required. As processor power increases, so does the amount of electrical energy consumed by the processor. Typical high power processors are disposed within modules in a vehicle, and each module is associated with at least one control system. As these high power electronic modules (HPEMs) operate and consume electricity, a substantial amount of heat is generated. Moreover, HPEMs may be located in areas within the vehicle, such as within the engine bay, where they are subjected to significant ambient temperatures. Prolonged thermal stress can have deleterious effects on HPEMs ranging from degrading or fracturing soldered connections to directly effecting a processor's operational speed, and eventually to causing complete processor failure. To mitigate thermal effects HPEMs are often actively cooled by way of liquid and/or air cooling.

However, while current thermal enclosures for HPEMs achieve their intended purpose in many applications, there is a need for new and improved thermally controlled enclosures for high power electronics with improved robustness, lifespan, redundancy, modularity, and with improved heat dissipating capabilities.

### SUMMARY

According to one aspect of the present disclosure an enclosure for convection cooling an electronic module in a motor vehicle includes a cold plate for mounting the electronic module thereon; a cover attached to the cold plate. The cover and the cold plate define a cavity; a plurality of inlets formed in the cover in fluid communication with the cavity; a plurality of outlets formed in the cover in fluid communication with the cavity, the outlets spaced apart from and opposite the inlets; an inlet manifold disposed in fluid communication with the plurality of inlets; and a plurality of fans disposed in fluid communication with the cavity, each of the plurality of fans having an inlet side in fluid communication with an outlet side.

In another aspect of the present disclosure an enclosure for convection cooling an electronic module further includes a thermal conduit disposed in the cold plate and extending from a thermal inlet to a thermal outlet. The thermal inlet is adjacent the outlets in the cover, and the thermal outlet is adjacent the inlets in the cover.

In yet another aspect of the present disclosure the thermal conduit is a liquid cooling conduit.

In yet another aspect of the present disclosure the cold plate is a Peltier device.

In yet another aspect of the present disclosure air enters the cavity through the inlets in the cover via the inlet manifold, and air exits the cavity through the outlets in the cover.

In yet another aspect of the present disclosure the inlet side of each of the plurality of fans is connected to the inlet manifold, and the outlet side of each of the plurality of fans is connected to one of the plurality of inlets in the cover.

In yet another aspect of the present disclosure an enclosure for convection cooling an electronic module further includes an outlet manifold. The inlet side of each of the plurality of fans is connected to one of the plurality of outlets in the cover, and the outlet side of each of the plurality of fans is connected to the outlet manifold.

In yet another aspect of the present disclosure cover is connected to the cold plate by an electromagnetic compatibility (EMC) gasket.

In yet another aspect of the present disclosure each of the plurality of inlets in the cover and each of the plurality of outlets in the cover is fully enclosed by an electromagnetic compatibility (EMC) material.

In yet another aspect of the present disclosure the enclosure and the EMC material block electromagnetic emissions.

In yet another aspect of the present disclosure an enclosure for convection cooling an electronic module in a motor vehicle includes a cold plate for mounting the electronic module thereon, a thermal conduit being disposed in the cold plate and extending from a thermal inlet to a thermal outlet; a cover attached to the cold plate. The cover and the cold plate define a cavity; a plurality of inlets formed in the cover in fluid communication with the cavity; a plurality of outlets formed in the cover in fluid communication with the cavity, the outlets spaced apart from and opposite the inlets; an inlet manifold disposed in fluid communication with the plurality of inlets; a plurality of fans disposed in fluid communication with the cavity, each of the plurality of fans having an inlet side in fluid communication with an outlet side. The thermal inlet is adjacent the outlets in the cover, and the thermal outlet is adjacent the inlets in the cover, and air enters the cavity through the inlets in the cover via the inlet manifold, and air exits the cavity through the outlets in the cover.

In yet another aspect of the present disclosure the cover further includes an inlet plate having the plurality of inlets; an outlet plate spaced apart from and opposite the inlet plate, the outlet plate having the plurality of outlets; a first side plate connected at an angle to the inlet plate and the outlet plate, the first side plate connected at an angle to a top plate and connected at an angle to a bottom plate, a second side plate spaced apart from and opposite the first side plate and connected at an angle to the inlet plate and the outlet plate, the second side plate connected at an angle to the top plate and connected at an angle to the bottom plate.

In yet another aspect of the present disclosure at least one of the top plate and the bottom plate is the cold plate.

In yet another aspect of the present disclosure the inlet plate is connected to the first side plate and the second side plate and the top plate and the bottom plate by a dielectrically conductive EMC gasket material, and the outlet plate is connected to the first side plate and the second side plate and the top plate and the bottom plate by the EMC gasket material.

In yet another aspect of the present disclosure each of the plurality of inlets in the cover and each of the plurality of outlets in the cover is fully enclosed by an electromagnetic compatibility (EMC) material optimized to block electromagnetic emissions.

In yet another aspect of the present disclosure each of the plurality of fans provides redundancy for at least another one of the plurality of fans.

In yet another aspect of the present disclosure each of the plurality of fans operates at about 50% capacity.

In yet another aspect of the present disclosure a fan speed of each of the plurality of fans is optimized to maintain an enclosure cavity temperature of below about 398K

In yet another aspect of the present disclosure a fan speed of each of the plurality of fans is optimized to maintain an enclosure cavity temperature of between about 293K and about 358K.

In yet another aspect of the present disclosure a fan speed of each of the plurality of fans is optimized to maintain an enclosure cavity temperature of between about 293K and about 313K.

In yet another aspect of the present disclosure the cold plate comprises a high thermal conductivity material and the cold plate is a Peltier device.

In yet another aspect of the present disclosure an enclosure for convection cooling an electronic module in a motor vehicle, the enclosure includes an inlet plate having a plurality of inlets, an electromagnetic compatibility (EMC) material covering each of the plurality of inlets; an outlet plate spaced apart from the inlet plate, the outlet plate having a plurality of outlets sized to minimized radiated electromagnetic emissions; a first side plate connected at an angle to the inlet plate and the outlet plate, the first side plate extending from the inlet plate to the outlet plate, the first side plate connected at an angle to a top plate and connected at an angle to a bottom plate, a second side plate spaced apart from the first side plate and connected at an angle to the inlet plate and the outlet plate, the second side plate connected at an angle to the top plate and connected at an angle to the bottom plate; each of the first side plate, the second side plate, the top plate, the bottom plate, the inlet plate, and the outlet plate being electrically bonded to a dielectrically conductive EMC gasket material; an inlet manifold disposed in fluid communication with the plurality of inlets of the inlet plate; a plurality of fans convection cooling the thermal enclosure and disposed in fluid communication with the thermal enclosure, each of the plurality of fans having an inlet side and an outlet side in fluid communication with the inlet side, the inlet side of each of the plurality of fans connected to the inlet manifold, and the outlet side of each of the plurality of fans disposed proximate to the inlet plate at a distance optimized to minimize a pressure differential between the plurality of fans and the thermal enclosure, and the outlet side of each of the plurality of fans is in fluid communication with one of the plurality of inlets in the inlet plate and the inlet side of each of the plurality of fans is in fluid communication with the inlet manifold. At least one of the top plate and the bottom plate is a liquid cooled high thermal conductivity cold plate, a thermal conduit being disposed in the cold plate and extending from a thermal inlet to a thermal outlet. The thermal inlet is adjacent the outlets in the outlet plate, and the thermal outlet is adjacent the inlets in the inlet plate, and the electronic module is mounted directly to the cold plate.

Further areas of applicability will become apparent from the description provided herein. It should be understood that the description and specific examples are intended for purposes of illustration only and are not intended to limit the scope of the present disclosure.

### DRAWINGS

The drawings described herein are for illustration purposes only and are not intended to limit the scope of the present disclosure in any way. In the drawings:

FIG. 1 is a top perspective view of a thermal enclosure according to one aspect of the present disclosure;

FIG. 2 is a bottom perspective view of a thermal enclosure according to an aspect of the present disclosure;

FIG. 3 is a partial cutaway top perspective view of a thermal enclosure according to an aspect of the present disclosure; and

FIG. 4 is a partial cutaway top perspective view showing airflow through a thermal enclosure according to an aspect of the present disclosure.

### DETAILED DESCRIPTION

The following description is merely exemplary in nature and is not intended to limit the present disclosure, application, or uses.

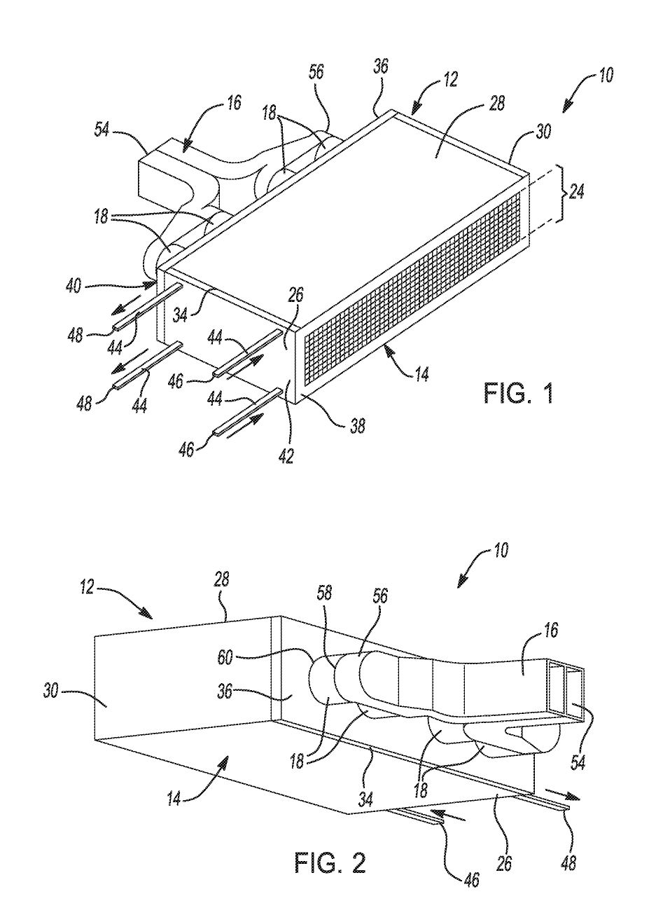

Referring to FIGS. 1 and 2, a first example of a thermal enclosure according to the present disclosure is shown and indicated generally by reference number 10. The thermal enclosure 10 of the present disclosure may be used in a variety of different positions, and for a variety of different purposes within a motor vehicle. However, for ease of understanding, the bulk of the disclosure will focus on thermal enclosures 10 for housing and providing forced convection cooling to electronic componentry within the motor vehicle. In one aspect, the thermal enclosure 10 includes a cover 12, a cold plate 14, an inlet manifold 16, and a plurality of fans 18. Each of the cover 12 and the cold plate are made of a high thermal conductivity material having electromagnetic emission suppression properties, such as magnesium, iron, copper, or the like. However, because the thermal enclosure 10 is fitted to a motor vehicle, it may be desirable for the weight of the thermal enclosure 10 to be minimized. Thus, while the material composition of the cover 12 and the cold plate 14 may vary, the materials will be chosen to optimize weight, cost, and the like on an application-specific basis. Likewise, the materials chosen for the inlet manifold 16 may vary according to the specific application. Thus, in various aspects, the inlet manifold 16 is composed of metals, thermally resilient plastics, polymers, silicone, or the like.

The cover 12 and the cold plate 14 define and enclose a cavity 20. The cavity 20 is in fluid communication with the inlet manifold 16 via a plurality of inlets 22, and the cavity 20 is also in fluid communication with ambient surroundings of the enclosure 10 by way of a plurality of outlets 24. In one aspect, each of the plurality of inlets 22 is a substantially circular opening, however the plurality of inlets 22 may vary in size, shape, and number depending on the particular application. Likewise, the plurality of outlets 24 is depicted as a plurality of slit-like openings, however it should be understood that the plurality of outlets 24 may vary in number, size, and shape substantially depending on the application. For example, the plurality of outlets 24 may be a plurality of circular, ovoid, or rectilinear holes, or the outlets 24 may be metal mesh grid without departing from the scope or intent of the present disclosure.

In one aspect, the thermal enclosure 10 substantially approximates a rectilinear box. In one aspect, the cover 12 includes a first side plate or portion 26 connected to a top plate or portion 28, and a second side plate or portion 30 spaced apart from and opposite to the first side portion 26. The second side portion 30 is also connected to the top portion 28. The cover 12 engages with the cold plate 14 at an interface surface 34 via an electromagnetic compatibility (EMC) material gasket. The EMC gasket creates a mechanical seal between the cover 12 and the cold plate 14, and also creates an electromagnetic connection between the cover 12 and the cold plate 14. Thus, to fully encapsulate the cavity 20, the EMC gasket extends for an entire perimeter of the interface surface 34 of the cover 12 where the cover 12 engages with the cold plate 14.

In a first example, the cover 12 is a unitary component including the first side portion 26, the top portion 28, and the second side portion 30. The cover 12 is mounted to and electromagnetically connected to the cold plate 14 by the EMC gasket. The plurality of inlets 22 are formed through the cover 12 and the plurality of outlets 24 are formed through the cover 12 and positioned such that the plurality of outlets 24 are spaced apart from and opposite the plurality of inlets 22. The cover 12 of the first example may take a variety of different forms depending on the application for which the thermal enclosure 10 is intended. Thus, in some aspects, the cover 12 of the first example may be hemispheric, or take any number of polyhedral three-dimensional shapes optimally sized and shaped for the particular application.

In a second example, the first side portion 26, the top portion 28, and the second side portion 30 are formed integrally with each other and have a substantially U-shaped cross section. The plurality of inlets 22 are formed through an inlet plate 36, and the plurality of outlets 24 are formed through an outlet plate 38. The inlet plate 36 is shaped to engage with a first end 40 of the cover 12. The first end of the cover 12 is defined by the portions of the first side portion 26, top portion 28, and second side portion 30 of the cover 12 proximate to the inlet manifold 16. The outlet plate 38 is similarly shaped to engage with a second end 42 of the cover 12. The inlet plate 36 is mounted to the first end 40 of the cover 12, and to the cold plate 14 by the EMC gasket. The outlet plate 38 is also mounted to the second end 42 of the cover 12, and to the cold plate 14 by the EMC gasket. Likewise, the cover 12 is mounted to the cold plate 14 by the EMC gasket. The second end 42 of the cover 12 is defined by the portions of the first side portion 26, top portion 28, and second side portion 30 of the cover 12 spaced apart from and opposite the inlet plate 36 and the inlet manifold 16.

In a third example, each of the first side portion 26, the top portion 28, and the second side portion 30 are formed separately and distinctly from each other. The first side portion 26 is assembled with the top portion 28 with the EMC gasket sandwiched therebetween. The second side portion 30 is also assembled with the top portion 28 with the EMC gasket therebetween, thereby forming the cover 12. As with the second example, in the third example, the inlet plate 36 and the outlet plate 38 are shaped to engage with and disposed at the first end 40 and the second end 42 of the cover 12 respectively. More specifically, the inlet plate 36 is assembled with the first end 40 of the cover 12 with the EMC gasket sandwiched between the first end 40 and the inlet plate 36. Similarly, the outlet plate 38 is assembled with the second end 42 of the cover 12 with the EMC gasket sandwiched between the outlet plate 38 and the second end 42.

While in the foregoing examples, the cover 12 has variously been described as being composed of a single unitary part, three distinct components, or five distinct components, it should be understood that depending on the application the number of parts composing the cover 12 may vary. That is, depending on the application, packaging constraints, thermal and cavity 20 capacity requirements, the thermal enclosure 10 may vary in size and be optimized by taking a variety of other shapes. Additionally, it should be understood that while the thermal enclosure 10 has been described as having only a single cold plate 14, the thermal enclosure 10 may include any number of cold plates 14, each of which replacing one of the first side portion 26, the top portion 28, and the second side portion 30 without departing from the scope or intent of the present disclosure. Thus, in some aspects, the top portion 28 and the bottom portion 30 may both be cold plates 14, as shown and indicated in FIG. 1.

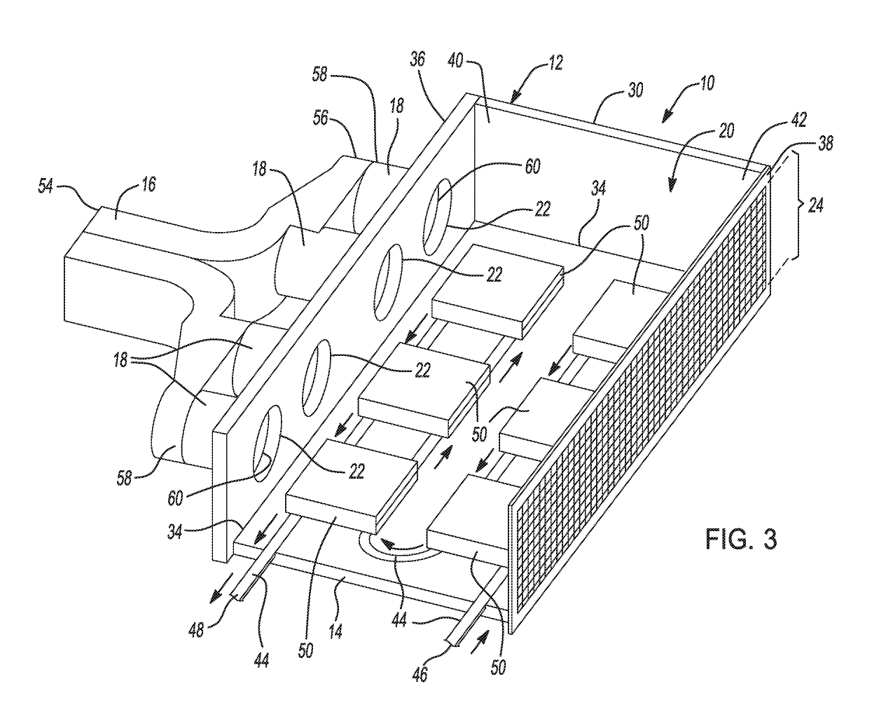

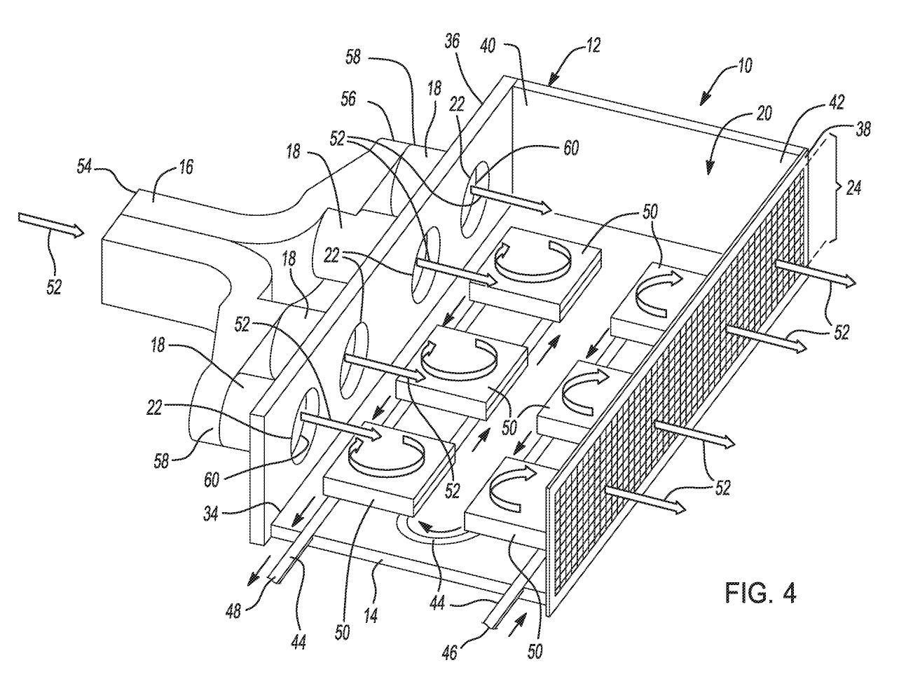

Turning now to FIGS. 3 and 4 and with continuing reference to FIGS. 1 and 2, the cold plate 14 includes a thermal conduit 44 extending from a thermal inlet 46 to a thermal outlet 48. The thermal conduit 44 is disposed in the cold plate 14 and in some aspects the thermal conduit 44 is formed as a passage through the cold plate 14. The thermal inlet 46 is adjacent the plurality of outlets 24 and the thermal outlet 48 is adjacent the plurality of inlets 22. In some aspects, a fluid pump (not shown) pumps liquid coolant through the thermal conduit 44 from the thermal inlet 46 to the thermal outlet 48. Electronic modules 50 are mounted directly to the cold plate 14 within the cavity 20 of the thermal enclosure 10. The electronic modules 50 may be described as non-generalized, electronic control devices having a preprogrammed digital computer or processor (not shown), memory or non-transitory computer readable medium (not shown) used to store data such as control logic, instructions, image data, lookup tables, etc., and a plurality of input/output peripherals or ports (not shown). The processor is configured to execute the control logic or instructions, and the controller may have additional processors or additional integrated circuits in communication with the processor, or with other processors within the module 50.

Electronic modules 50 such as Advanced Driver Assistance Systems (ADAS), engine control units (ECUs), transmission control units (TCUs), body control modules (BCMs), and the like may be better described as systems using high power electronic modules (HPEMs) 50. HPEMs 50 produce significant heat as a byproduct of operation. Since HPEMs 50 operate optimally at below approximately 85° Celsius (358K) and begin to degrade and fail at around 125° Celsius (398K) providing thermal relief to the HPEMs 50 is desirable. Therefore, for every incremental degree that the cavity 20 temperature can be reduced below about 85° C., the lifespan and performance of the HPEMs 50 housed within the thermal enclosure 10 is increased. In some examples the HPEMs 50 operate optimally and have desirable longevity if the HPEMS 50 are maintained at between about 20° C. and 85° C. (293K-358K). In further examples, the HPEMs 50 may operate optimally and have lifespans of 7-20 years if they are maintained at operational temperatures of between about 20° C. and about 40° C. (293K-313K). Therefore, in some aspects, and in some applications, mounting the HPEMs 50 to a cold plate 14 having a plurality of fins (not shown), or using a Peltier device (not shown) to cool the HPEMs 50 may be sufficient. However, in other aspects, and in higher ambient temperature locations such as vehicle engine compartments and the like, mounting HPEMs 50 directly to a liquid-cooled cold plate 14 and within the thermal enclosure 10 is desirable.

Referring once more to the cold plate 14, as depicted in FIG. 4, as liquid coolant flows from the plurality of thermal inlet 46 to the thermal outlet 48, thermal energy is transferred from the HPEMs 50 to the liquid coolant. Thus, the temperature of the liquid coolant at the thermal inlet 46 is substantially lower than the temperature of the liquid coolant at the thermal outlet 48.

Cooling air 52 is drawn through an intake 54 of the inlet manifold 16 and into the plurality of inlets 22 via an output 56 of the inlet manifold 16. Air 52 then flows across the thermal enclosure 10 generally passing from the plurality of inlets 22 to the plurality of outlets 24. In several aspects, the intake 54 draws air 52 from ambient surroundings of the thermal enclosure 10, from the heating ventilation and air conditioning (HVAC) system of the vehicle (not shown), or from any of a variety of other sources depending on the application in which the thermal enclosure 10 used. The output 56 is in fluid communication with the cavity 20 of the thermal enclosure 10. Thus, air 52 drawn into the intake 54 of the inlet manifold 16 is fluidly communicated to the cavity 20, thereby cooling the HPEMs 50 by way of convection. The inlet manifold 16 is structured and shaped to distribute air 52 optimally across the cavity 20. In an aspect, the air 52 is distributed evenly across each of the plurality of inlets 22. Air 52 is expelled from the cavity 20 by the plurality of outlets 24. As the air 52 flows from the plurality of inlets 22 to the plurality of outlets 24 thermal energy is transferred from the HPEMs 50 to the air 52 by convection. Thus, the temperature of the air 52 at the plurality of inlets 22 is substantially lower than the temperature of the air 52 at the plurality of outlets 24.

By orienting the thermal inlet 46 of the cold plate 14 so that it is adjacent the plurality of outlets 24 and by placing the thermal outlet 48 adjacent the plurality of inlets 22 a substantially similar temperature for each of the HPEMs 50 within the thermal enclosure 10 may be achieved. That is, by having a contra-flow system in which air 52 passes across the thermal enclosure 10 in a direction generally opposite that of the liquid coolant in the cold plate 14, heat transferred to the air 52 by the HPEMs 50 is mitigated by heat transferred to the liquid coolant by the HPEMs 50. In other words, the heat gradient of the air 52 is substantially opposite the heat gradient of the liquid coolant in the cold plate 14, thereby allowing the thermal enclosure 10 to maintain a substantially even temperature for each of the HPEMs 50 housed therein.

The fans 18 are positioned to draw air 52 into and through the thermal enclosure 10. In some aspects, the fans 18 are electrically powered and include an inlet side 58 in fluid communication with an outlet side 60. The fans 18 are sized and arranged in fluid communication with the thermal enclosure 10 to provide sufficient air flow through the thermal enclosure 10 to maintain an optimal temperature range for the HPEMs 50 housed therein. In one example, each of the fans 18 is mounted directly over at least one of the plurality of inlets 22. In the example, the inlet side 58 of each of the fans 18 is mounted to the inlet manifold 16 and the outlet side 60 is mounted directly to at least one of the plurality of inlets 22. In a second example, the inlet manifold 16 is mounted directly to the thermal enclosure 10 and the inlet side 18 of each of the fans 18 is mounted directly to the outlets 24 of the thermal enclosure 10. In the second example the fans 18 operate to exhaust air 52 from the cavity 20 of the thermal enclosure 10.

In one example, the fans 18 are arranged in pairs so that each individual fan 18 operates at approximately 50% capacity under optimal circumstances. Thus, if one fan 18 of a pair is operating sub-optimally, the other fan 18 of the pair balances out the deficit by increasing operational speed, thereby maintaining optimal air 52 flow through the thermal enclosure 10. While the fans 18 have been described herein as operating in pairs, it should be understood that any number of fans 18 may be grouped in operation together to provide optimal air 52 convection cooling to the HPEMs 50. For example, in a thermal enclosure 10 having four fans 18, if a first fan 18 in the series of four fans completely fails to operate, a fan speed controller (not shown) may increase the speed of the adjacent fan 18 from 50% to 100%. Alternately, the fan speed controller may increase the speeds of each of the remaining three fans 18 by an amount that maintains the overall volume and directionality of the air 52 flowing through the thermal enclosure 10.

Depending on the application, the number of HPEMs 50 within the thermal enclosure 10 may vary. In order to package the HPEMs 50 thermally and spatially efficiently, as the number of HPEMs 50 increases, so does the overall size of the thermal enclosure 10. Similarly, as the number of HPEMs 50 within the thermal enclosure 10 varies, the number of fans 18 and the volumetric efficiencies of the fans 18 may also vary. Thus, while the thermal enclosure 10 of FIGS. 1-4 includes four fans 18 to provide convection cooling to six HPEMs 50 as shown in FIGS. 3 and 4, it should be understood that the number of fans 18 and the number of modules 50 may vary substantially depending on the application for which the thermal enclosure 10 is intended. Similarly, the number of fans 18 may vary relative to the number of HPEMs 50 depending on the specifications of the fans 18 and the thermal enclosure 10 relative to the thermal requirements of the HPEMs 50 contained therein. For example, in some instances it may be desirable to contain ADAS, ECU, TCU, and BCM, as well as other such control systems within a single thermal enclosure 10. Thus, if each of the control systems in the example includes six HPEMs 50, the thermal enclosure 10 might include a total of twenty-four HPEMs 50 and sixteen fans 18 if the same ratio of fans 18 to modules 50 persists.

Lastly, because HPEMs 50 produce electromagnetic emissions that may interfere with telecommunications systems, navigations systems, and vehicle systems, the thermal enclosure 10 blocks such electromagnetic emissions. That is, the thermal enclosure 10 operates as a Faraday cage to block such electromagnetic emissions from exfiltrating the enclosure 10. To effectively block HPEM 50 emissions, each of the plurality of inlets 22 and each of the plurality of outlets 24 is fitted with EMC material (not specifically shown) porous enough to not substantially impede airflow. In one aspect, the EMC material is a metallic lattice having openings sized approximately 1/20th of the wavelength of the signals to be blocked. In another aspect, the EMC material is sized to block transmissions via Bluetooth, and 2.4 Ghz to 5 Ghz signals. However, it should be understood that the EMC material may vary depending on the particular electromagnetic emissions to be blocked. Thus, the thermal enclosure 10 operates as an EMC safe box as well as providing thermal cooling to the HPEMs 50 housed therein.

The thermal enclosure 10 of the present disclosure offers several advantages. These include light weight, ease of manufacture, low cost, simplicity of construction, redundancy, resiliency, and improved longevity. The description of the present disclosure is merely exemplary in nature and variations that do not depart from the gist of the present disclosure are intended to be within the scope of the present disclosure. Such variations are not to be regarded as a departure from the spirit and scope of the present disclosure.

What is claimed is:

1. An enclosure for convection cooling an electronic module in a motor vehicle, the enclosure comprising:
a cold plate for mounting the electronic module thereon;
a cover attached to the cold plate, wherein the cover and the cold plate define a cavity;
a plurality of inlets formed in the cover in fluid communication with the cavity;
a plurality of outlets formed in the cover in fluid communication with the cavity, the outlets spaced apart from and opposite the inlets;
an inlet manifold disposed in fluid communication with the plurality of inlets; and
a plurality of fans disposed in fluid communication with the cavity, each of the plurality of fans having an inlet side in fluid communication with an outlet side.

2. The enclosure for convection cooling an electronic module of claim 1 further comprising:
a thermal conduit disposed in the cold plate and extending from a thermal inlet to a thermal outlet, wherein the thermal inlet is adjacent the outlets in the cover, and wherein the thermal outlet is adjacent the inlets in the cover.

3. The enclosure for convection cooling an electronic module of claim 2 wherein the thermal conduit is a liquid cooling conduit.

4. The enclosure for convection cooling an electronic module of claim 2 wherein the cold plate is a Peltier device.

5. The enclosure for convection cooling an electronic module of claim 2 wherein air enters the cavity through the inlets in the cover via the inlet manifold, wherein air exits the cavity through the outlets in the cover.

6. The enclosure for convection cooling an electronic module of claim 1 wherein the inlet side of each of the plurality of fans is connected to the inlet manifold, and the outlet side of each of the plurality of fans is connected to one of the plurality of inlets in the cover.

7. The enclosure for convection cooling an electronic module of claim 1 further comprising an outlet manifold wherein the inlet side of each of the plurality of fans is connected to one of the plurality of outlets in the cover, and the outlet side of each of the plurality of fans is connected to the outlet manifold.

8. The enclosure for convection cooling an electronic module of claim 1 wherein the cover is connected to the cold plate by an electromagnetic compatibility (EMC) gasket.

9. The enclosure for convection cooling an electronic module of claim 1 wherein each of the plurality of inlets in the cover and each of the plurality of outlets in the cover is fully enclosed by an electromagnetic compatibility (EMC) material.

10. The enclosure for convection cooling an electronic module of claim 9 wherein the enclosure and the EMC material block electromagnetic emissions.

11. An enclosure for convection cooling an electronic module in a motor vehicle, the enclosure comprising:
a cold plate for mounting the electronic module thereon, a thermal conduit being disposed in the cold plate and extending from a thermal inlet to a thermal outlet;
a cover attached to the cold plate, wherein the cover and the cold plate define a cavity;
a plurality of inlets formed in the cover in fluid communication with the cavity;
a plurality of outlets formed in the cover in fluid communication with the cavity, the outlets spaced apart from and opposite the inlets;
an inlet manifold disposed in fluid communication with the plurality of inlets;
a plurality of fans disposed in fluid communication with the cavity, each of the plurality of fans having an inlet side in fluid communication with an outlet side;
wherein the thermal inlet is adjacent the outlets in the cover, and the thermal outlet is adjacent the inlets in the cover, and wherein air enters the cavity through the inlets in the cover via the inlet manifold, and air exits the cavity through the outlets in the cover.

12. The enclosure of claim 11 wherein the cover further comprises:
an inlet plate having the plurality of inlets;
an outlet plate spaced apart from and opposite the inlet plate, the outlet plate having the plurality of outlets;
a first side plate connected at an angle to the inlet plate and the outlet plate, the first side plate connected at an angle to a top plate and connected at an angle to a bottom plate, a second side plate spaced apart from and opposite the first side plate and connected at an angle to the inlet plate and the outlet plate, the second side plate connected at an angle to the top plate and connected at an angle to the bottom plate.

13. The enclosure of claim 12 wherein at least one of the top plate and the bottom plate is the cold plate.

14. The enclosure of claim 12 wherein the inlet plate is connected to the first side plate and the second side plate and the top plate and the bottom plate by a dielectrically conductive EMC gasket material, and wherein the outlet plate is connected to the first side plate and the second side plate and the top plate and the bottom plate by the EMC gasket material.

15. The enclosure of claim 11 wherein each of the plurality of inlets in the cover and each of the plurality of outlets in the cover is fully enclosed by an electromagnetic compatibility (EMC) material optimized to block electromagnetic emissions.

16. The enclosure of claim 11 wherein each of the plurality of fans provides redundancy for at least another one of the plurality of fans.

17. The enclosure of claim 11 wherein each of the plurality of fans operates at about 50% capacity.

18. The enclosure of claim 11 wherein a fan speed of each of the plurality of fans is optimized to maintain an enclosure cavity temperature of below about 398K.

19. The enclosure of claim 18 wherein a fan speed of each of the plurality of fans is optimized to maintain an enclosure cavity temperature of between about 293K and about 358K.

20. The enclosure of claim 18 wherein a fan speed of each of the plurality of fans is optimized to maintain an enclosure cavity temperature of between about 293K and about 313K

21. The enclosure of claim 11 wherein the cold plate comprises a high thermal conductivity material and wherein the cold plate is a Peltier device.

22. An enclosure for convection cooling an electronic module in a motor vehicle, the enclosure comprising:
an inlet plate having a plurality of inlets, an electromagnetic compatibility (EMC) material covering each of the plurality of inlets;
an outlet plate spaced apart from the inlet plate, the outlet plate having a plurality of outlets sized to minimized radiated electromagnetic emissions;
a first side plate connected at an angle to the inlet plate and the outlet plate, the first side plate extending from the inlet plate to the outlet plate, the first side plate connected at an angle to a top plate and connected at an angle to a bottom plate, a second side plate spaced apart from the first side plate and connected at an angle to the inlet plate and the outlet plate, the second side plate connected at an angle to the top plate and connected at an angle to the bottom plate; each of the first side plate, the second side plate, the top plate, the bottom plate, the inlet plate, and the outlet plate being electrically bonded to a dielectrically conductive EMC gasket material;
an inlet manifold disposed in fluid communication with the plurality of inlets of the inlet plate;
a plurality of fans convection cooling the thermal enclosure and disposed in fluid communication with the thermal enclosure, each of the plurality of fans having an inlet side and an outlet side in fluid communication with the inlet side, the inlet side of each of the plurality of fans connected to the inlet manifold, and the outlet side of each of the plurality of fans disposed proximate to the inlet plate at a distance optimized to minimize a pressure differential between the plurality of fans and the thermal enclosure, and wherein the outlet side of each of the plurality of fans is in fluid communication with one of the plurality of inlets in the inlet plate and the inlet side of each of the plurality of fans is in fluid communication with the inlet manifold,
wherein at least one of the top plate and the bottom plate is a liquid cooled high thermal conductivity cold plate, a thermal conduit being disposed in the cold plate and extending from a thermal inlet to a thermal outlet, wherein the thermal inlet is adjacent the outlets in the outlet plate, and wherein the thermal outlet is adjacent the inlets in the inlet plate, and wherein the electronic module is mounted directly to the cold plate.
